(19) United States
(12) Patent Application Publication
(10) Pub. No.: US 2025/0372488 A1
(43) Pub. Date: Dec. 4, 2025

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventor: Paolo CREMA, Vimercate (IT)

(73) Assignee: STMicroelectronics International N.V., Geneva (CH)

(21) Appl. No.: 19/214,519

(22) Filed: May 21, 2025

(30) Foreign Application Priority Data
May 30, 2024 (IT) 102024000012331

(51) Int. Cl. H01L 23/495; H01L 21/48; H01L 21/56; H01L 21/683; H01L 21/768; H01L 23/00

(52) U.S. Cl. CPC H01L 23/49568; H01L 21/4828; H01L 21/4871; H01L 21/565; H01L 21/6835; H01L 23/49548; H01L 24/48; H01L 21/561; H01L 21/7684; H01L 23/49513; H01L 24/32; H01L 24/73; H01L 24/96; H01L 24/97; H01L 2224/32245; H01L 2224/48245; H01L 2224/73265; H01L 2224/96; H01L 2224/97; H01L 2924/1815

(57) ABSTRACT

A core pattern of thermally conductive formations and electrically conductive formations is formed extending through an insulating layer laminated onto a carrier foil. A semiconductor chip or die is arranged onto the insulating layer so that the insulating layer supports the semiconductor chip or die and the thermally conductive formations of the core pattern provides a heat propagation path from the semiconductor chip or die and the electrically conductive formations of the core pattern provides contact leads for the semiconductor chip or die. A pattern of further electrically conductive formations is provided to electrically couple the semiconductor chip or die to selected ones of the electrically conductive formations in the core pattern. The carrier foil is removed and singulation is performed to provided individual packaged devices.

### PRIORITY CLAIM

This application claims the priority benefit of Italian application for Patent No. 102024000012331, filed on May 30, 2024, the content of which is hereby incorporated by reference in its entirety to the maximum extent allowable by law.

### TECHNICAL FIELD

The description relates to semiconductor devices. Aspects of the present description can be used, for instance, in manufacturing power integrated circuit (IC) semiconductor devices. Aspects of the present description can be applied, for instance, to manufacturing semiconductor devices with Quad-Flat No-leads (QFN) packages.

### BACKGROUND

A conventional Quad-Flat No-leads (QFN) package structure usually comprises a substrate (leadframe) including a die pad onto which an (integrated circuit—IC) semiconductor chip or die is mounted via die attach material. The substrate includes an array of leads around the die pad that are electrically coupled to the semiconductor chip or die via electrically conductive formations such as wires of a wire bonding pattern.

Technology currently referred to as panel level package (PLP) technology can be applied to manufacturing semiconductor devices via a sequence of steps. PLP technology is regarded as hardly suited to be applied to manufacturing QFN format packages, primarily due to possible issues related to heat draining (sinking).

Manufacturing IC semiconductor devices such as IC devices with QFN packages without having to rely on (external) leadframe suppliers would be advantageous and desirable.

Facilitating adoption of PLP technology for QFN format packages is likewise desirable in so far as resorting to PLP technology facilitates implementing a thoroughly “internal” manufacturing process.

United States Patent Application Publication No. 2022/0189885 A1 (incorporated by reference) describes a packaged device carrier having a board side surface and an opposing surface, the packaged device carrier having conductive leads having a first thickness spaced from one another; the conductive leads having a head portion attached to a dielectric portion, a middle portion extending from the head portion and extending away from the board side surface of the packaged device carrier at an angle to the opposing surface, and each lead having an end extending from the middle portion with a foot portion configured for mounting to a substrate.

United States Patent Application Publication No. 2023/0143539 A1 (incorporated by reference) is exemplary of the possibility of arranging a semiconductor die on a substrate and molding an encapsulation of laser direct structuring (LDS) material onto the semiconductor die. Through mold vias (TMV) extending through the encapsulation include a collar section that extends through a first portion of the encapsulation from an outer surface to an intermediate level of the encapsulation, and a frusto-conical section that extends from a bottom of the collar section through a second portion of the encapsulation. The collar section has a first cross-sectional area at the intermediate level. The first end of the frusto-conical section has a second cross-section area at the intermediate level. The second cross-sectional area is smaller than the first cross-sectional area. Such a TMV can have an aspect ratio which is not limited to 1:1.

United States Patent Application Publication No. 2023/0067918 A1 (incorporated by reference) discloses a leadframe-less laser direct structuring (LDS) semiconductor package including a first laser direct structuring (LDS) resin layer and a second LDS resin layer on the first LDS resin layer. Respective surfaces of the first LDS resin layer and the second LDS resin layer are patterned utilizing an LDS process by exposing the respective surfaces to a laser. Patterning the first and second LDS resin layers, respectively, activates additive material present within the first and second LDS resin layers, respectively, converting the additive material from a non-conductive state to a conductive state. The LDS process is followed by a chemical plating step and an electrolytic plating process to form conductive structure coupled to a plurality of die within the first and second LDS resin layers. A molding compound layer is formed on surfaces of the conductive structures and covers the surfaces of the conductive structures. After these steps have been completed, the first LDS resin layer and the second LDS resin layer are singulated along channels filled with conductive material.

Other background information on related art can be gathered from United States Patent Application Publication Nos. 2022/0109282 A1, 2014/0367848 A1, and 2022/0238473 A1, U.S. Pat. No. 10,615,146 B2, and PCT Application No. WO 2017/102230 A1 (all incorporated by reference).

There is a need in the art to contribute in addressing the issues discussed in the foregoing.

### SUMMARY

One or more embodiments relate to a method.

One or more embodiments relate to a corresponding (integrated circuit—IC) semiconductor device.

Solutions as described herein facilitate manufacturing IC semiconductor devices such as QFN packages without having to rely on (external) leadframe suppliers, while also facilitating the use of PLP technology in connection with QFN format packages.

Solutions as described herein facilitate manufacturing key elements of a QFN package (leads, die pad) by additive manufacturing, starting, for instance, from a copper foil laminated on a wafer or panel format substrate (e.g., stainless steel) which can be overmolded with molding compound.

The molding compound can be a conventional molding compound such as an epoxy molding compound (EMC), for instance.

Advantageously, the compound can be a laser direct structuring (LDS) compound (also referred to as a direct copper interconnection (DCI) or laser direct writing (LDW) compound or with the trade designation LISI™).

In solutions as described herein, a QFN format package can be formed without resorting to a metal leadframe by molding a compound on a metal foil (copper, for instance), and forming therein (via laser beam energy applied, for instance) lead and die pad vias or cavities that are filled with electrically conductive material (by electroplating, for instance) with the possibility of optionally planarizing the structure top surface.

Solutions as described herein are compatible with various alternatives to provide electrical die-to-lead coupling such as wire bonding or LDS (DCI, LDW, LISI™) processing. Also, PLP-like finishing and forming a slug may facilitate coming up with a so-called slug-up QFN package.

Solutions as described herein thus facilitate providing a chip or a die that is attached and coupled to leads either using a LDS, DCI, LDW, LISI™ or a PLP-like approach or using standard wire bonding while dispensing with a conventional leadframe by laminating onto a sacrificial carrier (a copper foil, for instance) an overmolded molding compound, with the possibility of creating a slug up QFN package.

In solutions as described herein, through mold vias (TMVs) and top openings can be formed at “future” die pad and lead locations by laser beam processing, for instance.

Solutions as described herein also facilitate filling by electroplating plus optionally planarizing the structure top surface.

### BRIEF DESCRIPTION OF THE DRAWINGS

One or more embodiments will now be described, by way of example only, with reference to the annexed figures, wherein:

FIG. 1 illustrates the basic structure of an (integrated circuit—IC) semiconductor device with a QFN package;

FIGS. 2A to 2S illustrate possible steps in applying panel level package (PLP) technology in manufacturing semiconductor devices; and

FIGS. 3A to 3K illustrate possible steps in manufacturing semiconductor devices using solutions as described herein.

### DETAILED DESCRIPTION

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for each figure for the sake of brevity.

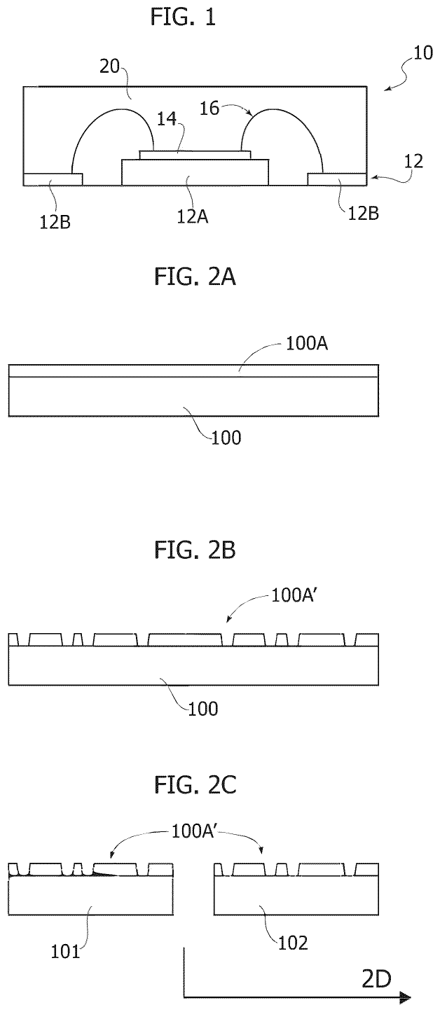

FIG. 1 illustrates the basic structure of an (integrated circuit—IC) semiconductor device 10 with a Quad Flat No-lead (QFN) package including: a substrate (leadframe) having one or more semiconductor chips or dice arranged thereon; electrically conductive formations such as wires coupling the semiconductor chip(s) to leads (outer pads) in the substrate; and an insulating encapsulation (a resin, for instance) molded on the assembly thus formed to complete the plastic body of the device.

In a power semiconductor device, the current transferred from a high-power section to the output pads of the device can be significant and ribbons or clips are used for that purpose in the place of wires with wires still used to provide electrical coupling to a low-power section (e.g., a controller) in the device.

More in detail, an integrated circuit (IC) semiconductor device 10 as illustrated in FIG. 1 comprises a substrate (leadframe) 12 having arranged thereon one or more semiconductor chips or dice 14.

Throughout this description the terms chip/s and die/dice are used as synonymous.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe 12 comprises one more die pads 12A configured to have at least one semiconductor chip or die 14 attached thereon. This may be via conventional means such as a die attach adhesive (a die attach film (DAF), for instance).

A leadframe 12 as illustrated in FIG. 1 also comprises an array of electrically-conductive formations (or leads) 12B that from an outline location extend inwardly in the direction of the semiconductor chip(s) or die/dice 14 thus forming an array of electrically-conductive formations therefor.

A device 10 including a single die pad 12A having attached thereon a single chip or die 14 is illustrated for simplicity in FIG. 1.

A device 10 as illustrated in FIG. 1 is intended to be mounted on a substrate such as a printed circuit board (PCB), not visible in the figures, using solder material, for instance.

Electrically conductive formations 16 are provided to electrically couple the semiconductor chip 14 to selected ones of the leads (outer pads) 12B in the leadframe 12. As illustrated in FIG. 1, these electrically conductive formations comprise wires 16 providing a wire bonding pattern. The wires 16 are coupled to die pads (not visible for reasons of scale) provided at the front or top surface of the chip 14.

As already discussed, in the case of power devices, so-called ribbons or clips can be used in the place of wires to electrically couple the chip 14 to selected ones of the leads 12B that act as (power) output pads of the device 10.

Using or ribbons in the place of wires as included in the wire bonding patterns 16 is advantageous in those cases where the current transferred from a (power) chip or die 14 to the output pads in a power semiconductor device may be significant.

An insulating encapsulation 20 (e.g., an epoxy resin) can be molded on the assembly thus formed to complete the plastic body of the device 10.

A more detailed description of a device 10 as discussed is not provided herein in so far as such a device structure can be regarded as conventional in the art.

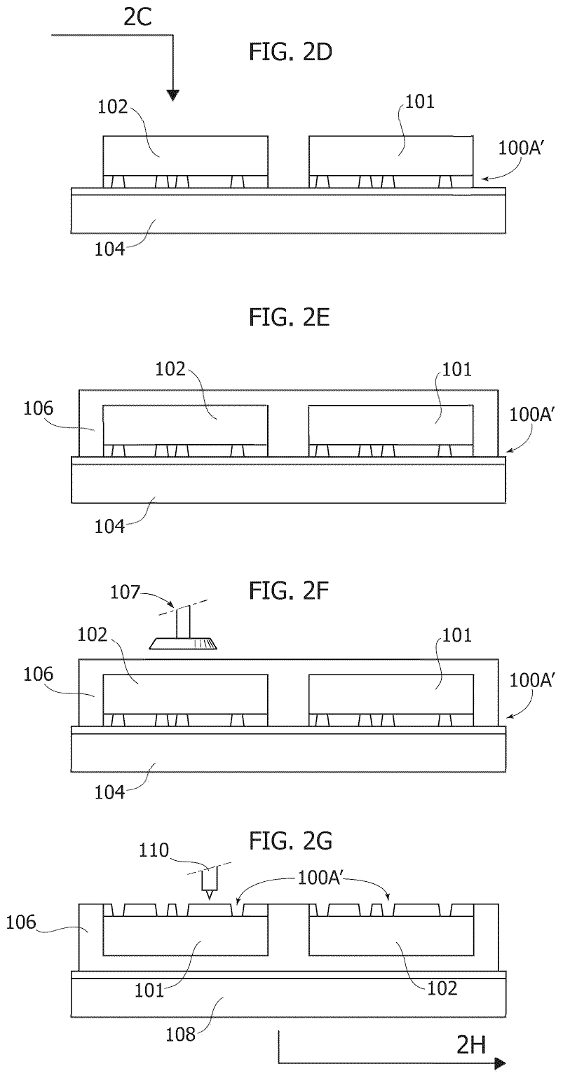

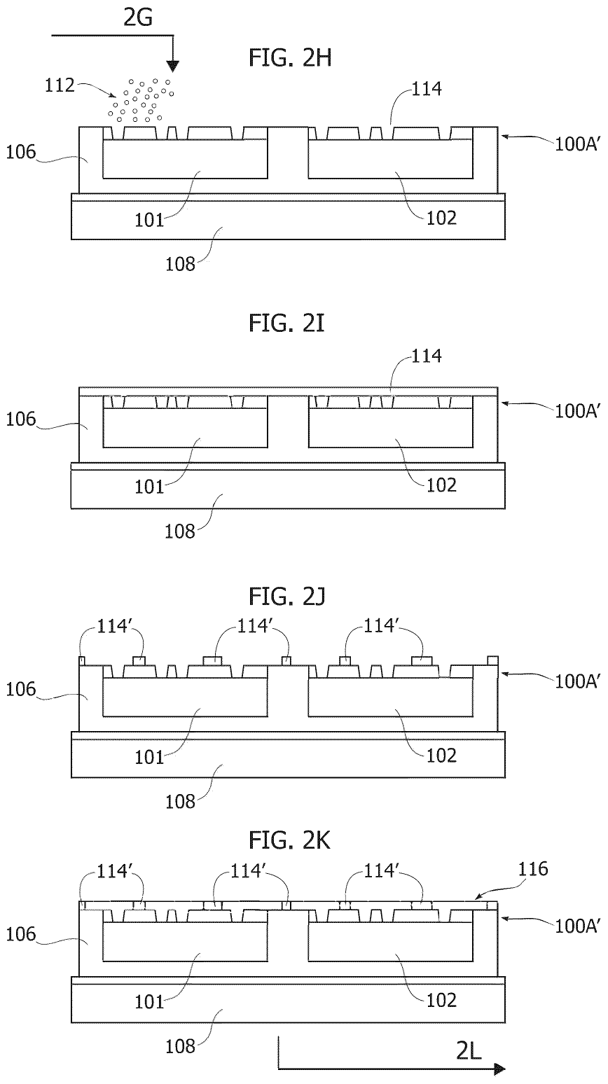

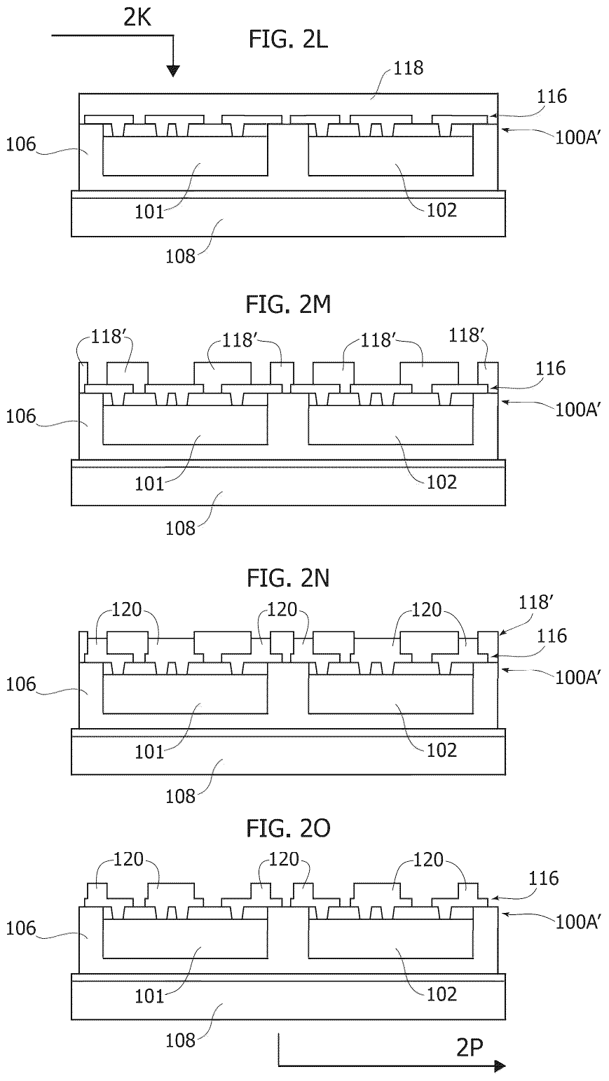

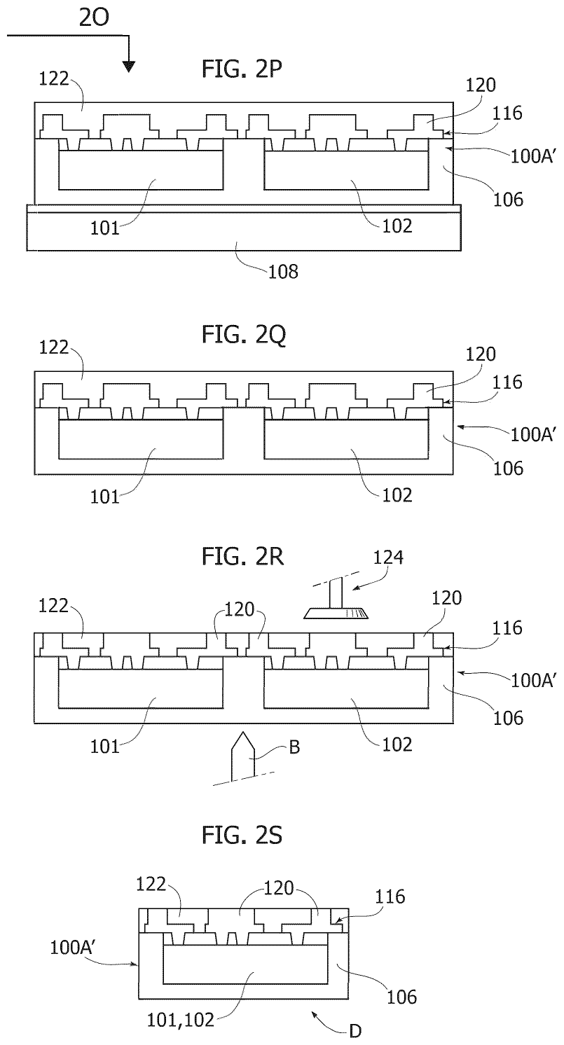

FIGS. 2A to 2S illustrate possible steps in applying panel level package (PLP) technology in manufacturing (integrated circuit—IC) semiconductor devices.

Here again, PLP technology can be regarded as per se conventional in the art.

By way of summary, manufacturing a semiconductor device with PLP technology may include steps as illustrated in FIG. 2A to 2S.

For simplicity, the steps discussed in the following will be referred to with the number of the figure where they are exemplified:
step 2A—lamination of a semiconductor wafer 100 with an insulating film 100A such as and Ajinomoto Build-Up Film® (ABF);
step 2B—forming of vias in the film 100A′ via laser and/or plasma etching;
step 2C—wafer grinding and dicing to produce separate die portions 101, 102;
step 2D—“flipping” the assembly previously formed and panel reconstruction using a carrier 104 such as a stainless-steel carrier;
step 2E—molding a molding compound 106 onto the die portions 101, 102;
step 2F—grinding with a grinding tool 107 the molding compound 106;
step 2G—releasing from the carrier 104, transferring onto a new carrier 108 (after renewed flipping) and automated optical inspection (AOI) as indicated at reference 110;
step 2H—sputter treatment 112 (TiCu, for instance);
step 2I—laminating a dry film 114;
step 2J—laser direct imaging (LDI) processing and developing of dry film as indicated at reference 114′;
step 2K—via/trace plating (Cu, for instance) as indicated at reference 116;
step 2L—stud dry film lamination as indicated at reference 118;
step 2M—laser direct imaging (LDI) processing and developing of dry film 118 as indicated at reference 118′;
step 2N—stud plating (Cu, for instance) as indicated at reference 120;
step 2O—stripping of dry film 118 and TiCu (for instance) etching of studs 120;
step 2P—lamination of a (further) insulating film 122 such as Ajinomoto Build-Up Film® (ABF);
step 2Q—panel debond (remove from carrier 108);
step 2R—grinding of insulating film via a tool 124; and
step 2S—singulation (blade B in FIG. 2R) to provide individual devices D.

It will be otherwise appreciated that the sequence of steps of FIGS. 2A to 2S is merely exemplary in so far as: one or more steps illustrated in FIGS. 2A to 2S can be omitted, performed in a different manner (with other tools, for instance) and/or replaced by other steps; additional steps may be added; and one or more steps can be carried out in a sequence different from the sequence illustrated.

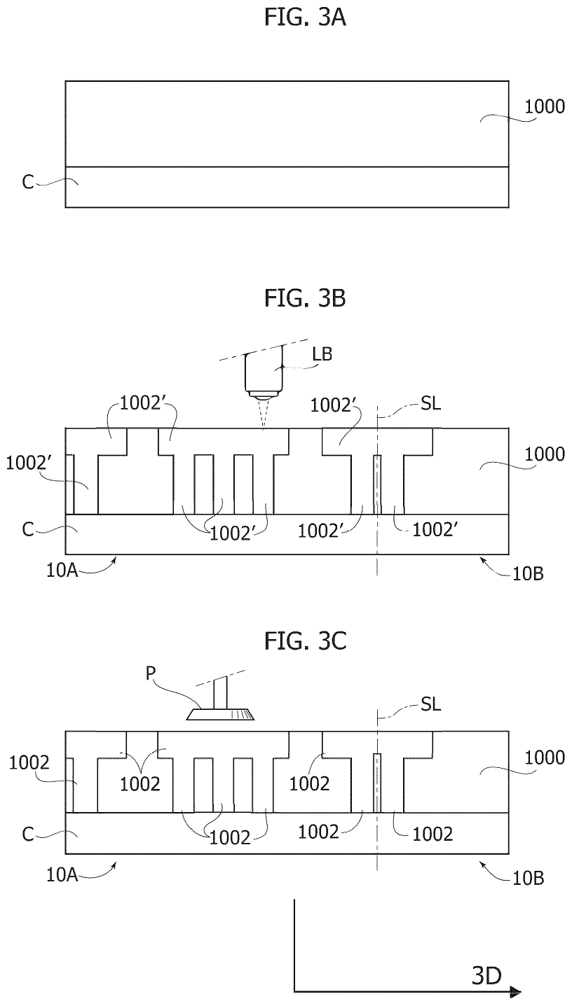

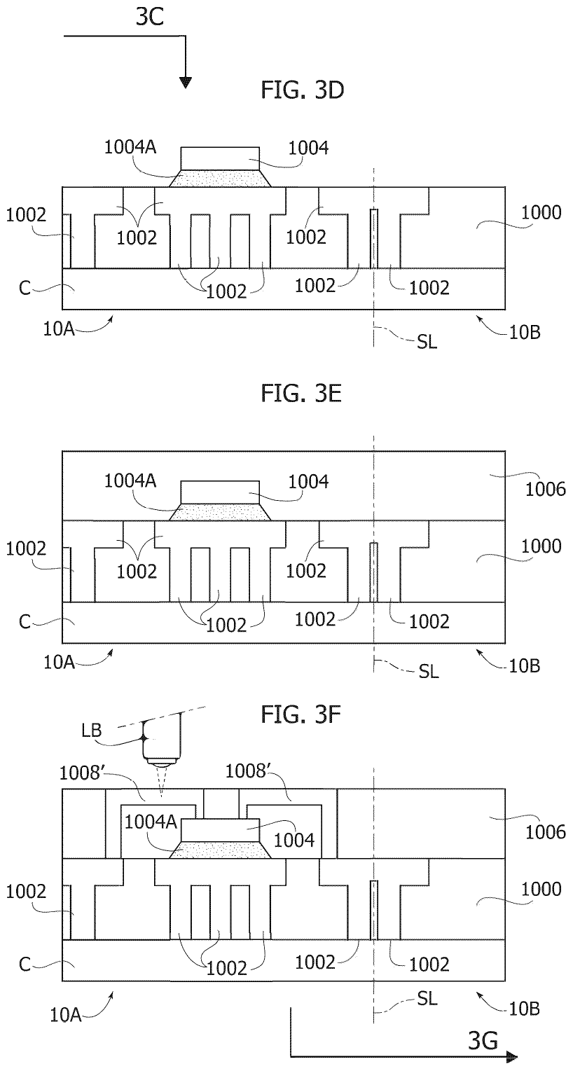

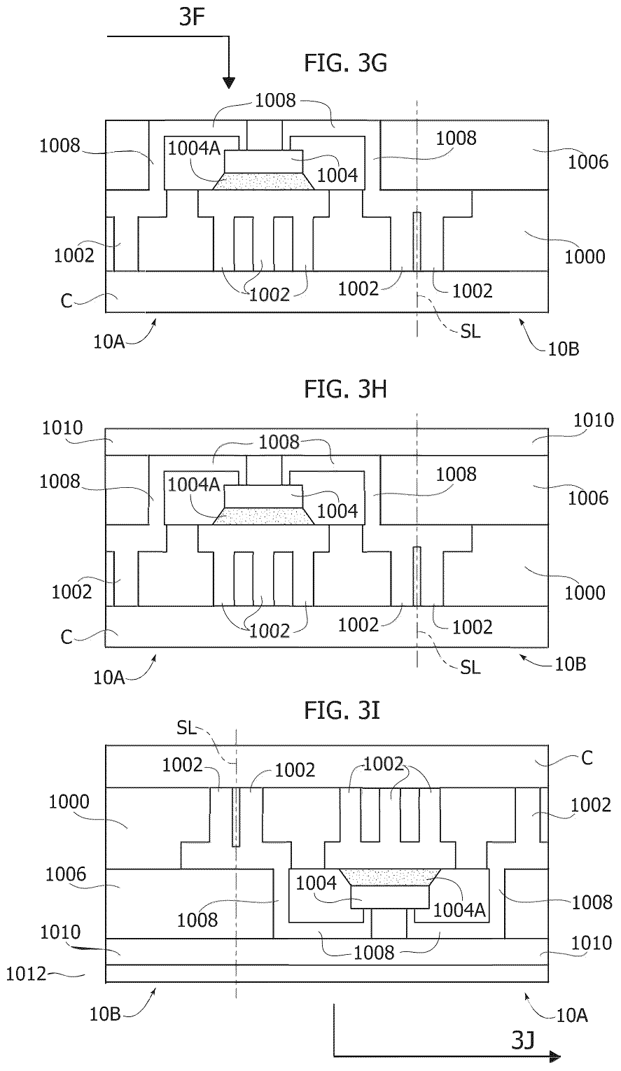

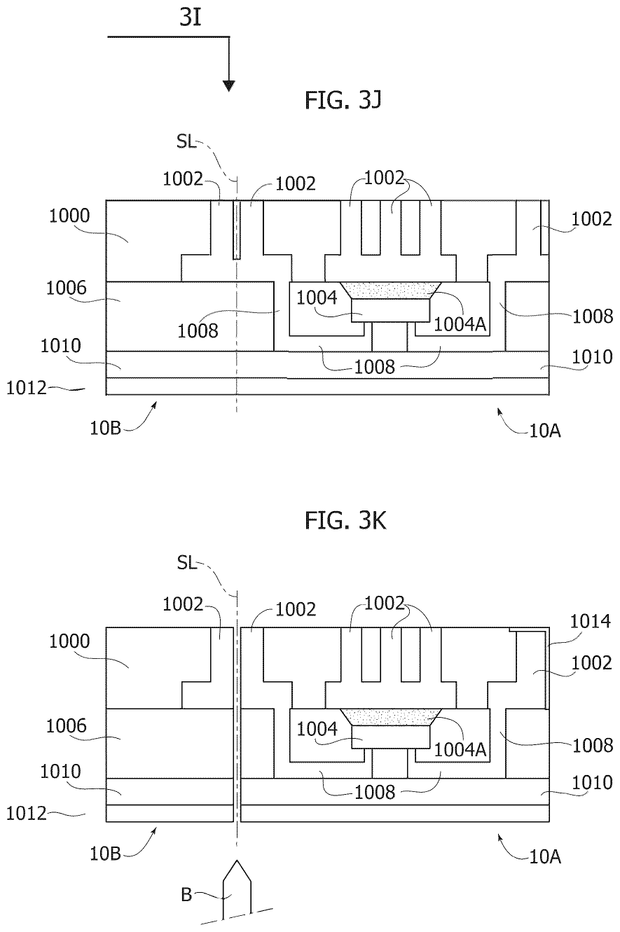

It will be likewise appreciated that, even though not expressly mentioned, one or more of the implementation options or steps illustrated in FIG. 1 and FIGS. 2A to 2S can be used also in connection with the steps of the method of manufacturing semiconductor devices as described herein in connection with FIGS. 3A to 3K.

This may apply, for instance, to the possibility—illustrated in FIG. 1—of electrically coupling a semiconductor chip 14 with selected ones of the outer pads 12B in a device 10 via wires 16 of a wire bonding pattern with an insulating encapsulation 20 (e.g., an epoxy resin) molded on the assembly thus formed to complete the plastic body of the device 10.

FIG. 3A is illustrative of a molding compound 1000 being molded onto a carrier C such as a metal carrier including, for instance, a copper plate configured to hold a molded package of 50 μm thickness, for instance.

The designation carrier (in the place of substrate) and the use of a letter as a reference (in the place of a number), is intended to highlight the sacrificial nature of the carrier C. The carrier C is in fact intended to be used in various steps in a method as described herein and to be finally removed (dispensed with): by way of example, the carrier C is no longer illustrated in FIGS. 3J and 3K.

Various options are available for the choice of the molding compound 1000.

This may be a conventional molding compound (an epoxy resin, for instance) or an “activatable” molding compound such as an LDS molding compound (as discussed more extensively in the following in connection with figures from FIG. 3E onwards).

FIG. 3B is exemplary of the possibility, whatever the solution adopted for the molding compound 1000, of applying thereto laser beam energy (indicated as LB) to “pattern” (namely to sculpture) therein a distribution of lead and die pad vias or cavities 1002′ that are subsequently filled by electroplating as illustrated in FIG. 3C.

In that way a desired pattern of thermally (and electrically) conductive formations 1002 can be created for one or more (integrated circuit—IC) semiconductor chips or dice to be subsequently arranged thereon as discussed in in the following in connection with FIG. 3D.

Referring to the core pattern of formations 1002 as including thermally and electrically conductive formations highlights the fact that: some of the formations in the core pattern 1002 can advantageously act as heat sinks (heat cooling pillars) to drain therefrom heat generated in operation by a semiconductor chip or die arranged thereon as illustrated in FIG. 3E; and some of the formations in the core pattern 1002 can advantageously act as outer leads or pads for a resulting device by being coupled to electrically conductive formations such as wires (see wires 16 in FIG. 1) or die-to-lead formations 1008 as illustrated in figures from FIG. 3G onwards.

It is noted that the lead and die pad cavities 1002′ “drilled” in the layer 1000 as exemplified in FIG. 3B are indicated there with an accent (′): this is intended to highlight the fact that the core pattern of thermally and electrically conductive formations 1002 formed in the insulating layer 1000 results from conductive material (metal such as copper, for instance) being provided (via electroplating, for instance) into those cavities 1002′.

The desired location and routing of the thermally/electrically conductive formations in the core pattern 1002 is dictated by the desired device characteristics.

Likewise, the specific details of providing the lead and die pad cavities 1002′ and the electrically conductive formations 1002 depends on a variety of factors, including, for instance, the choice of the molding compound 1000.

Laser drilling and electroplating are thus referred to herein primarily by way of example. Etching (such as plasma etching, for instance) can be mentioned as a possible alternative to laser beam energy to form the cavities 1002′ in the insulating layer 1000 results.

Likewise, various options other than electroplating can be used to form, for instance, metallized holes in one or more of the vias/cavities 1002′. Electroless plating followed by electrolytic plating may be mentioned by way of example.

Whatever the specific implementation options, the formations 1002 can be regarded as providing a core (or base) pattern configured to support one or more integrated circuit (IC) semiconductor devices attached thereon (at the surface opposite the carrier C) as further detailed in the following.

Reference to PLP technology as discussed previously in connection with FIGS. 2A to 2S, facilitates appreciating that steps as illustrated in FIGS. 3A to 3K lend themselves to being performed on a carrier C and an insulating layer 1000 laminated thereon that include portions configured to “embrace” plural devices as highlighted by the references 10A and 10B lying on opposite sides of an (at first just notional) separation border line SL between adjacent devices 10 that are manufactured using a common carrier C and insulating layer 1000.

FIG. 3C is also exemplary of the possibility of (optionally) planarizing, using a planarizing tool P, the front or top surface of the structure at which the thermally/electrically conductive formations 1002 have been provided.

FIG. 3D is exemplary of the step of attaching one or more (integrated circuit—IC) semiconductor chips or dice 1004 onto that (possibly planarized) surface using die attach material such as die attach film (DAF) 1004A.

As noted, the terms chip or die are used as synonymous throughout this description.

Also, while a single chip or die 1004 is illustrated herein for simplicity, plural chips or dice can be mounted in either of both sections 10A and 10B.

FIG. 3E is exemplary of a protective/insulating encapsulation of (further) molding material 1006 molded onto the chip or die 1004 attached on the insulating layer 1000 having formed therein (therethrough) to core pattern of thermally and electrically conductive formations 1002.

The encapsulating material 1006 may be a conventional molding compound (an epoxy resin, for instance). In that case, prior to molding such a compound, electrically conductive formations for the chip or die 1004 can be provided with wires of a wire bonding pattern the couples die pads (not visible for reasons of scale) provided at the front or top surface of the chip or die 1004 with selected ones of the electrically conductive formations 1002 intended to act as outer lead connections for a final semiconductor device.

Such an option is not visible in the sequence of FIGS. 3A to 3K, in so far as it essentially corresponds to the possibility—illustrated in FIG. 1—of electrically coupling a semiconductor chip to selected ones of the outer pads in a device via wires of a wire bonding pattern with an insulating encapsulation (e.g., an epoxy resin) molded on the assembly thus formed to complete the plastic body of the device.

In the sequence of FIGS. 3A to 3K, FIGS. 3F to 3K are exemplary of selecting for the encapsulation 1006 an “activatable” molding compound such as an LDS molding compound.

Laser direct structuring (LDS) is a laser-based machining technique now widely used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP are currently available for that purpose.

A laser beam can be used to transfer (“structure” or “write”) a desired electrically conductive pattern onto a plastic molding that may then be subjected to metallization to finalize a desired conductive pattern.

Metallization may involve electroless plating followed by electrolytic plating.

Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

LDS is referred to also as laser direct writing (LDW) or as direct copper interconnection (DCI). This is primarily with reference to a package family wherein conventional wire bonding is replaced with copper plated vias and lines (traces).

The trade designation LISIPACK™ is also used where LISI stands for laser-induced strip interconnection.

United States Patent Application Publication Nos. US 2018/0342453 A1, 2019/0115287 A1, 2020/0203264 A1, 2020/0321274 A1, 2021/0050226 A1, 2021/0050299 A1, 2021/0183748 A1, 2021/0305203 A1 or 2023/0143539 A1 (already mentioned)—all incorporated herein by reference—are exemplary of the possibility of applying LDS (DCI, LDW, LISIPACK™) technology in manufacturing semiconductor devices.

FIG. 3F is exemplary of the possibility of applying laser beam energy (again indicated as LB) to selected locations in an LDS encapsulation 1006 to “pattern” therein a distribution of vias and traces 1006′ that are subsequently filled by electroplating (electroless plus electrolytic plating, for instance) as illustrated in FIG. 3G in order to finalize therein a desired pattern of electrically conductive formations 1008 for the integrated circuit, IC semiconductor chip or die 1004.

It is once more noted that the lead and die pad vias and traces 1008′ as exemplified in FIG. 3F are indicated there with an accent (′) to evidence the fact that the electrically conductive formations 1008 result from conductive material (metal such as copper, for instance) being provided (grown via electroplating, for instance) therein.

For instance, LDS technology facilitates replacing wires, clips or ribbons with lines/vias created by laser beam processing of an LDS material followed by metallization (growing metal such as copper via a plating process, for instance).

Electrically conductive die-to-lead coupling formations 1008 can be provided (as discussed in the commonly assigned applications cited in the foregoing, for instance) in the LDS encapsulation 1006 (once consolidated, e.g., via thermosetting) with these die-to-lead coupling formations comprising: first through mold vias (TMVs) that extend through the LDS encapsulation 1006 between the top (front) of the LDS encapsulation 1006 and electrically-conductive pads (not visible for scale reasons) at the front or top surface of the chip or die 1004; second through mold vias (TMVs) that extend through the LDS encapsulation 1006 between the top (front) surface of the LDS encapsulation 16 and corresponding formations 1002 intended to act as outer leads or pads of the resulting device; and electrically-conductive lines or traces that extend at the front or top surface of the LDS encapsulation 1006 and electrically couple selected ones of the first vias with selected ones of the second vias to provide a desired die-to-lead electrical connection (routing) pattern between the chip or die 1004 and the outer leads or pads of the final device.

Electrical components (passive components such as resistors, for instance) may be possibly arranged along one or more of the lines or traces.

The desired location and routing pattern of the electrically conductive formations 1008 is dictated by the desired device characteristics.

FIGS. 3H and 3I are exemplary of a solder mask 1010 applied onto the encapsulation 1006 having the formations 1008 provided therein.

Thereafter and/or concurrently therewith: the resulting assembly can released/separated from the sacrificial carrier C (see the sequence of FIGS. 3I and 3J): for instance, the carrier C can be removed via chemical etching such as ammonia etching in the case of a copper carrier; the assembly can be possibly attached onto a flat support 1012; the portions 10A, 10B having the separation line (plane) SL therebetween are singulated via blade cutting as exemplified at B in FIG. 3K; and so-called wettable flanks as illustrated at 1014 in FIG. 3K can be provided via tin immersion.

It will be otherwise appreciated that the sequence of steps of FIGS. 3A to 3K is merely exemplary in so far as: one or more steps illustrated in FIGS. 3A to 3K can be omitted, performed in a different manner (with other tools, for instance) and/or replaced by other steps; additional steps may be added; and one or more steps can be carried out in a sequence different from the sequence illustrated.

This last point applies primarily to the step of releasing the device structure from the carrier C (by removing the carrier C via etching, for instance).

This step (here exemplified in the sequence of FIGS. 3I and 3J) may possibly take place at an earlier stage: in fact, the insulating layer 1000 having the core pattern of (metal) formation 1002 extending therethrough may provide already at an earlier stage adequate support for the chips or dice 1004 in providing the electrically conductive formations associated therewith (wire bonding wires, ribbons, clips or LDS-structured formations such as the formations 1008).

This may be the case, for instance, of an insulating layer 1000 comprising a certain thickness of resin.

In solutions as described herein, a core pattern of thermally and electrically conductive formations 1002 extending through an insulating layer 1000 (a molding compound resin, for instance) laminated onto a sacrificial carrier foil C effectively replaces a conventional leadframe in supporting one or more semiconductor chips or dice 1004 attached thereon providing a heat dissipation path therefrom as well as contact leads therefor.

This facilitates finalizing a thoroughly “internal” manufacturing process, without having to rely on “external” leadframe suppliers.

A further pattern of electrically conductive formations (wires in a wire bonding pattern or formations 1008 “structured” in LDS molding compound) can be provided to electrically couple the semiconductor chips or dice 1004 to selected ones of the electrically conductive formations 1002 in the core pattern.

A sacrificial metal foil (copper, for instance) can be used as the carrier foil C.

Advantageously, the insulating layer 1000 laminated onto the carrier foil C may comprise a plurality of portions 10A, 10B having a border line SL therebetween.

Solutions as described herein may contemplate cutting at the border line SL (advantageously, after removing the carrier foil C) the insulating layer 1000 having one or more semiconductor chips or dice 1004 arranged thereon with a further pattern of electrically conductive formations 1008 electrically coupling the semiconductor chip(s) or die/dice 1004 to selected ones of the electrically conductive formations 1002 in the core pattern 1002.

This facilitates manufacturing (integrated circuit—IC) semiconductor devices having a QFN format package (a package without a leadframe, thus a leadframe-less package) by resorting to a process that exhibits the advantages of PLP technology: FIGS. 3A to 3K seen in counterpoint with FIGS. 2A to 2S are exemplary of this.

Advantageously, forming the core pattern of thermally and electrically conductive formations 1002 through the insulating layer 1000 may comprise forming (via laser beam drilling or etching, for instance) cavities 1002′ extending through the insulating layer 1000, and metallizing the cavities 1002′ thus formed.

Without prejudice to the underlying principles, the details and embodiments may vary, even significantly, with respect to what has been described by way of example only, without departing from the extent of protection.

The claims are an integral part of the disclosure provided herein in respect of the embodiments.

The extent of protection is determined by the annexed claims.

1. A method, comprising:
laminating an insulating layer onto a carrier foil;
forming a core pattern of thermally conductive formations and electrically conductive formations extending through the insulating layer;
arranging at least one semiconductor chip or die onto the insulating layer, wherein the insulating layer supports the at least one semiconductor chip or die and wherein the thermally conductive formations of the core pattern provides a heat propagation path from the at least one semiconductor chip or die, and wherein the electrically conductive formations of the core pattern provides contact leads for the at least one semiconductor chip or die;
providing a pattern of further electrically conductive formations electrically coupling the at least one semiconductor chip or die to selected ones of the electrically conductive formations in said core pattern, and
removing the carrier foil.

2. The method of claim 1, wherein the insulating layer laminated onto the carrier foil comprises a plurality of portions having a border line therebetween and the method comprises cutting the insulating layer at the border line with the pattern of further electrically conductive formations electrically coupling the at least one semiconductor chip or die to the selected ones of the electrically conductive formations in said core pattern.

3. The method of claim 2, further comprising removing the carrier foil prior to cutting the insulating layer at the border line.

4. The method of claim 1, wherein forming the core pattern of thermally electrically conductive formations and electrically conductive formations through the insulating layer comprises:
forming cavities in and extending through the insulating layer; and
metallizing the cavities formed through the insulating layer.

5. The method of claim 4, wherein forming cavities comprises applying laser beam energy to the insulating layer to form said cavities.

6. The method of claim 1, further comprising providing a wire bonding pattern of electrically conductive wires electrically coupling the at least one semiconductor chip or die to selected ones of the electrically conductive formations in said core pattern.

7. The method of claim 1, further comprising:
molding a laser direct structuring compound onto the at least one semiconductor chip or die arranged onto the insulating layer laminated onto the carrier foil; and
applying laser beam energy to selected locations of the laser direct structuring compound to structure therein structures for said further electrically conductive formations electrically coupling the at least one semiconductor chip or die to selected ones of the electrically conductive formations in said core pattern.

8. The method of claim 7, comprising growing conductive material at said structures at the selected locations of the insulating layer.

9. A device, comprising:
an insulating layer;
a core pattern of thermally conductive formations and electrically conductive formations extending through the insulating layer;
at least one semiconductor chip or die arranged on the insulating layer wherein the insulating layer supports the at least one semiconductor chip or die and said thermally conductive formations of the core pattern provides a heat propagation path from the at least one semiconductor chip or die and said electrically conductive formations of the core pattern provides contact leads for the at least one semiconductor chip or die; and
a pattern of further electrically conductive formations electrically coupling the at least one semiconductor chip or die to selected ones of the electrically conductive formations in said core pattern.

10. The device of claim 9, further comprising a wire bonding pattern of electrically conductive wires electrically coupling the at least one semiconductor chip or die to selected ones of the electrically conductive formations in said core pattern.

11. The device of claim 9, further comprising laser direct structuring compound molded onto the at least one semiconductor chip or die arranged onto the insulating layer, and wherein said further electrically conductive formations are structured at selected locations of the laser direct structuring compound and configured to electrically couple the at least one semiconductor chip or die to selected ones of the electrically conductive formations in said core pattern.
